(19) United States
(12) Patent Application Publication
(10) Pub. No.: US 2024/0101850 A1
(43) Pub. Date: Mar. 28, 2024

(54) PRINTED CONFORMAL HIGH TEMPERATURE ELECTRONICS USING COPPER NANOINK

(71) Applicant: The Research Foundation for The State University of New York, Amherst, NY (US)

(72) Inventor: Shenqiang REN, Williamsville, NY (US)

(21) Appl. No.: 18/262,971

(22) PCT Filed: Jan. 27, 2022
(86) PCT No.: PCT/US2022/014170

§ 371 Date: Jul. 26, 2023

Related U.S. Application Data
(60) Provisional application No. 63/142,487, filed on Jan. 27, 2021.

(51) Int. Cl. C09D 11/52; C09D 11/03; H05K 1/09

(52) U.S. Cl. CPC C09D 11/52; C09D 11/03; H05K 1/092; H05K 2201/10098

(57) ABSTRACT

The present disclosure, in various examples, provides copper nanoparticle conductive inks and methods for making such conductive inks. The conductive ink may be deposited without the need for subsequent annealing. The conductive ink composition may include a slurry of copper nanoparticles in water. The copper nanowires may be made from copper or a copper alloy. The copper nanoparticles may be copper nanowires, such as high aspect ratio copper nanowires. The copper nanoparticles may be encapsulated by nickel, a nickel-rich material, zinc, aluminum, iron, or other metals or metal alloys.

### CROSS-REFERENCE TO RELATED APPLICATIONS

This application claims priority to U.S. Provisional Application No. 63/142,487, filed on Jan. 27, 2021, now pending, the disclosure of which is incorporated herein by reference.

### FIELD OF THE DISCLOSURE

The present disclosure relates to printable inks, and more particularly, conductive printable inks for electronic circuits.

### BACKGROUND OF THE DISCLOSURE

Each year, Cu is used in more than 60% of electrical applications due to its excellent electrical, thermal, and mechanical properties. The ever-increasing need for high-throughput electronic device miniaturization demands the printing of flexible hybrid electronics without sacrificing performance, light weight, and conformability. Printed electronics include emerging conductive material inks for integration on dielectric substrates, showing potential in transistors, batteries, photovoltaics, antennas, and electronic sensors. In this context, a number of conformal electronic device components are required to operate at high temperatures, for use in fields such as hypersonics, without sacrificing their lightweight and flexible natures. Such high-temperature operation poses significant material challenges. To overcome these challenges, high-temperature functional materials have been explored in manufacturing the electronics. Traditional ceramic materials offer excellent thermal stability, but generally undesirable brittle nature, when subjected to high temperatures. Therefore, alternative materials for high-temperature electronics would be printable and conformal, allowing them to be coated onto any artificial structural lattices.

Advantageous for the aforementioned printed electronics is the development of an electrically conductive ink with substrate binding ability. Recent conductive ink explorations use metallic nanoparticles, such as silver, copper, aluminum, or carbon conductors. However, the stabilizing agents or polymeric additives used in these processes need to be decomposed by high annealing temperatures to improve electrical conductivity. To date, the previously-demonstrated conductive inks utilizing nanoparticles typically exhibit low conductivity, environmental sensitivity, and high-temperature annealing. Unfortunately, these limitations render the metallic ink incompatible with many flexible substrates used in printable electronics. Therefore, there is a need to develop printable metallic inks which can be processed at ambient conditions, with oxidation-resistant natures that enable high-temperature electronics.

### BRIEF SUMMARY OF THE DISCLOSURE

The present disclosure provides an advantageous conductive ink which provides benefits including tunable viscosity for hybrid printing, high electrical conductivity without high-temperature annealing, environmental stability for a long lifetime, and/or scalability. In an aspect, we report all-printed flexible conformal electronics including Cu nanowire features (>10⁶ S/m) and dielectric substrates. High aspect ratio Cu nanowires enable a conductive percolation network after printing to produce a conductive trace onto a variety of artificial substrates. The electrical conductivity of printed Cu nanowires can be controlled by aqueous-based reaction and printing conditions. The stability of printed features is shown by Cu/Ni alloying (or other alloying/compositing with other materials) to effectively protect it from oxidation. We demonstrate a reflection coefficient of −60 dB at the resonant frequency of 2.5 GHz using flexible radio-frequency antenna by printing Cu nanowires on flexible ceramics. Such flexible antenna electronics also exhibit high sensitivity (0.05% ° C.⁻¹) and accuracy (15° C.) for real-time high-temperature sensing.

A composition of conductive ink is provided. Methods of making various compositions of the conductive ink are disclosed, as well as method of printing using the conductive ink.

We report conformal high-temperature electronics by integrating RF antenna devices for wireless communication with the high-temperature sensor through all-printed Cu conductor traces onto flexible ceramic substrates. We demonstrated that Cu nanowires can be tailored into a conductive printable ink without high-temperature annealing. High aspect ratio Cu nanowires enable a conductive percolation network after printing to produce a conductive trace onto a variety of artificial substrates, such as, for example, paper, glass, polyimide, polyvinylidene fluoride (PVDF), flexible ceramics, and the like. These printed Cu traces exhibit high stability under ambient conditions, which can be further improved by Cu/Ni alloying. Using highly conductive Cu traces onto dielectric flexible ceramic substrates, we demonstrate the dipole antenna applications, while the dynamic temperature control of dielectric constant further opens up the new avenues of high-temperature sensor electronics. With the integrated nature between RF antenna and temperature sensor, we expect the great promise of all-printed conformal high-temperature electronics by using economical Cu ink materials.

### DESCRIPTION OF THE DRAWINGS

For a fuller understanding of the nature and objects of the disclosure, reference should be made to the following detailed description taken in conjunction with the accompanying drawings, in which:

FIG. 1. Electrical conductivity of nanostructured Cu geometries. The SEM image of Cu nanoparticles (a), nanoparticles and nanorods (b), nanorods (c), and nanowires (d) after reaction times of 9, 11, 12, and 18 h, respectively. (e) Printed Cu features on a variety of substrates, including glass, Teflon, paper, Kapton, polyvinylidene fluoride (PVDF)-trifluoroethylene (TrFE), and flexible yttria-stabilized zirconia (YSZ) ceramic. (f) Electrical conductivity based on nanostructured Cu geometry. (g) Electrical conductivity at varying concentrations of hydroxypropyl cellulose.

FIG. 2. Effect of acid treatment and printed Cu feature thickness on electrical conductivity. (a) SEM image of printed Cu features before the solution acid treatment. (b) SEM image of printed Cu features after the solution acid treatment, showing the removal of residual organic material. (c) Current-voltage curves of printed 2 μm thick Cu features under different solution acid treatment time with the measurements taken from 0 to 30 s. (d) Solution treatment time-dependent electrical conductivity for 5 and 20 vol % dodecanoic acid. (e, f) Current-voltage curves of printed Cu features with the thickness of 4 and 12 respectively, under different solution acid treatment times with the measurements taken from 0 to 30 s.

FIG. 3. Electrical conductivity and air stability of printed Cu and Cu/Ni (core/shell) conductor. (a) Conductive stability of printed Cu conductor over a duration of 30 days in air. (b) Current-voltage curves of printed Cu and Cu/Ni features with different molar ratios between Cu and Ni element. (c) Electrical conductivities of printed Cu and Cu/Ni conductors. (d) Temperature-dependent electric conductivity of printed Cu and Cu/Ni conductors. (e) In situ X-ray diffraction (XRD) pattern of Cu conductor over a duration of 150 min at 150° C. (f) In situ XRD pattern of Cu/Ni conductor over a duration of 210 min at 150° C.

FIG. 4. Cyclic bending test and high-temperature conformal electronics. (a) Photograph representing the 120° bend angle of the printed flexible Cu-YSZ ceramic electronics during the 200 cycle bending test. (b) Current-voltage curve of printed Cu features onto the YSZ ceramics after thermal annealing at 800° C. for 10 min and relative resistance change during cyclic bending test over the duration of 200 cycles. (c) Schematic and photograph of printed Cu-YSZ RF antenna. (d) The S₁₁ for the effect of electrical conductivity on the resonant frequency for printed Cu-YSZ antenna devices. (e) The S₁₁ for the effect of thickness on the resonant frequency for printed Cu-YSZ antenna devices. (f) Temperature dependence of the relative permittivity for printed Cu-YSZ high-temperature electronics.

FIG. 5. Schematic Representation of the Development Process of a Copper Ink for Printable Electronics. (a) The chemical reaction of copper(II) chloride, hexadecylamine, and D-glucose in water for scalable nanostructured Cu growth. (b) The controllable Cu growth under different reaction times. (c) The addition of (hydroxypropyl)methylcellulose (HPMC) into Cu slurry for the printable ink formation. (d) Direct-write printing of the Cu ink onto a desired substrate. (e) Solution acid treatment of printed Cu features to remove organic additives for the increased conductivity.

FIG. 6. The XRD of Cu nanowires.

FIG. 7. a-c, TEM, d, SEM, e, EDS mapping of Cu nanowires, f-g, EDS mapping of Cu/Ni nanowires.

FIG. 8. a-b, Direct writing of Cu conductive features. c-d, The printed Cu conductor features for electrical connection with LED lightbulb.

FIG. 9. The I-V curve of 2 μm thickness Cu features with 5% acetic acid treatment (a), 20% acetic acid treatment (b), 50% acetic acid treatment (c), and 80% acetic acid treatment (d).

FIG. 10. The 2 μm thickness Cu features with different acetic acid treatment and SEM image of Cu features after the acid treatment.

FIG. 11. The I-V curve of 4 μm thickness Cu features with 50% acetic acid treatment (a), 80% acetic acid treatment (b), and the treatment time dependent conductivity (c).

FIG. 12. The I-V curve of 12 μm thickness Cu features with 80% acetic acid treatment (a), and treatment time dependent conductivity (b).

FIG. 13. The temperature dependent conductivity of printed Cu conductor features.

FIG. 14. The in-situ conductivity of no-treatment Cu conductor at different temperatures.

FIG. 15. relative resistance change of copper conductor without annealing during cyclic bending test over the duration of 200 cycles.

FIG. 16. Conductive stability of printed different Cu/Ni conductor over a duration of 30 days in air.

### DETAILED DESCRIPTION OF THE DISCLOSURE

Although claimed subject matter may be described in terms of certain examples, other examples, including examples that do not provide all of the benefits and features set forth herein, are also within the scope of this disclosure. Various structural, logical, and process step changes may be made without departing from the scope of the disclosure.

The present disclosure provides compositions, composite structures, and uses thereof.

In an aspect, the present disclosure provides compositions. In various examples, a composition is made by a method of the present disclosure. Non-limiting examples of compositions are provided herein (e.g., in the Example, sample claims, and elsewhere). A composition may be may be referred to as a conductive ink or a printable conductive ink.

The steps of the methods described in the various examples disclosed herein are sufficient to carry out the methods of the present disclosure. Thus, in an example, a method consists essentially of a combination of the steps of the methods disclosed herein. In another example, a method consists of such steps.

The present disclosure, in various examples, provides copper nanoparticle conductive inks and methods for making such conductive inks. In various examples, the conductive ink may be deposited without the need for subsequent annealing. In various examples, the conductive ink composition may include a slurry of copper nanoparticles in water. In various examples, the water may be deionized water. The copper nanowires may be made from copper or a copper alloy. In some embodiments, the copper nanoparticles may be copper nanowires, such as high aspect ratio copper nanowires. In some embodiments, nanowires include nanorods. The nanowires may have an diameter of 20-150 nm, inclusive, and all values in between, or the average diameter may be higher or lower than this range. In some embodiments, the distribution of the diameters of the nanowires may range from 20-80, inclusive, or any value therebetween. In a some embodiments, the average diameter of the nanowires is 90 nm, 95 nm, 100 nm, 105 nm, or 110 nm.

In some embodiments, the copper nanoparticles (e.g., nanowires, etc.) may be encapsulated by nickel, a nickel-rich material, zinc, aluminum, iron, or other metals or metal alloys. In some embodiments, the copper nanoparticles (e.g., nanowires, etc.) may be encapsulated in graphene. In some embodiments, the encapsulation has an average thickness ranging from 10-30 nm, inclusive, and all values in between or higher or lower. For example, the encapsulation may have a thickness of 20 nm. It is generally intended that the thickness of the encapsulation refers to the thickness of the encapsulating layer of mater (e.g., nickel, etc.)—i.e., the thickness of a shell, coating, or the like.

The conductive ink composition may include (hydroxypropyl)methyl cellulose (HPMC). In this way, the viscosity of the composition may be controlled according to the amount of HPMC (e.g., concentration). For example, the concentration of HPMC may be in the range of 1%-10%, inclusive and values in between, or the concentration may be higher or lower. In some embodiments, the concentration is between 2% and 5%, inclusive, and values in between.

In another aspect, the present disclosure provides a method for making a conductive ink composition as disclosed herein. The method may include contacting a copper salt, an aliphatic amine, D-glucose, and water to form a reaction mixture; and heating the reaction mixture to form the conductive ink composition. In some embodiments, the aliphatic amine may have from 10 to 20 carbon atoms, inclusive. In some embodiments, the aliphatic amine is hexadecylamine (HDA).

In some embodiments, the amounts of copper(II) chloride, D-glucose, and HDA in the reaction mixture are (in the following amounts or amounts based on the ratios of the following amounts): 2.4 g copper(II) chloride; 3.9 g D-glucose; 14.55 g HDA; and 900 mL water. In some embodiments, the molar concentrations of copper(II) chloride, D-glucose, and HDA in the reaction mixture are 19.83 mmol/L, 24.05 mmol/L, and 66.95 mmol/L, respectively.

The reaction mixture may also include a nickel salt, an iron salt, an aluminum salt, or a zinc salt. For example, in some embodiments, the reaction mixture includes nickel chloride, and the molar concentrations of copper(II) chloride, nickel chloride, D-glucose, and HDA in the reaction mixture are 9.92-17.85 mmol/L, 1.56-8.14 mmol/L, 24.05 mmol/L, and 66.95 mmol/L, respectively. In some embodiments, the amounts provided are (in the following amounts or amounts based on the ratios of the following amounts): 1.2-2.16 g copper(II) chloride (inclusive and all values in between); 0.182-0.950 g nickel chloride (inclusive and all values in between); 3.9 g D-glucose; 14.55 g HDA; and 900 mL water.

The reaction mixture is heated to a temperature ranging from 15° C. to 100° C. inclusive, and all values in between. For example, in some embodiments, the reaction mixture is heated to a temperature of 45° C., 50° C., 55° C., 60° C., 65° C., 70° C., 75° C., 80° C., 85° C., 90° C., or 95° C. In some embodiments, the temperature may be higher or lower than these ranges and values.

The reaction mixture may be heated for a period of time ranging from 5-48 hours, inclusive, and all values in between, For example, in some embodiments, the reaction mixture may be heated for 6, 9, 9.5, 10, 11, 12, and 18 hours. In some embodiments, the heating period of time may be higher or lower than these ranges and values.

The method may further include stirring the reaction mixture for a period of time ranging from 1-24 hours inclusive, and all values in between. For example, in some embodiments, the reaction mixture may be stirred for 6, 9, 9.5, 10, 11, 12, or 18 hours. In some embodiments, the stirring time may be higher or lower than these ranges and values.

The method may further include adding HPMC to the conductive ink composition. For example, the method may include mixing (hydroxypropyl)methylcellulose (HPMC) with water (e.g., deionized water) and adding the HPMC-water mixture to the conductive ink composition. In this way, the viscosity of the composition may be controlled according to the amount of HPMC (e.g., concentration) in the resulting conductive ink composition. For example, the concentration of HPMC may be in the range of 1%40%, inclusive and values in between, or the concentration may be higher or lower. In some embodiments, the concentration is between 2% and 5%, inclusive, and values in between.

In another aspect, the present disclosure provides a method of printing conductive ink. The method includes extruding any of the presently disclosed conductive ink compositions onto a substrate (as described herein). The extruded ink (on the substrate) is then washed with an acid (such as, for example, an organic acid) to remove residual aliphatic amine. In some embodiments, the method is performed without annealing the extruded ink (whether before and/or after the washing step).

The following examples are presented to illustrate the present disclosure, and not intended to be limiting in any matter.
Example 1. A conductive ink composition, comprising a slurry of copper nanoparticles in water.
Example 2. The conductive ink composition of example 1, wherein the copper nanoparticles are nanowires (e.g., having an average diameter ranging from 20-150 nm (inclusive, and all values in between or higher or lower), for example, a distribution of diameters ranging from 20-80 nm inclusive; an average diameter of 100 nm; other ranges or averages).
Example 3. The conductive ink composition of any of examples 1 or 2, wherein each of the copper nanoparticles comprises copper or a copper alloy.
Example 4. The conductive ink composition of example 3, wherein each of the copper nanoparticles is encapsulated by nickel (e.g., a nickel shell) a nickel-rich material, zinc, aluminum, iron, or other metals or metal alloys, or graphene.
Example 5. The conductive ink composition of example 4, wherein the nickel encapsulation has an average thickness ranging from 10-30 nm (inclusive, and all values in between or higher or lower), for example, an average thickness of 20 nm.
Example 6. The conductive ink composition of any one of examples 1-5, further comprising (hydroxypropyl)methyl cellulose (HPMC) (for example, weight percentage of HPMC (relative to the ranging from 1% to 10% (inclusive, and all values in between or higher or lower, for example, 2%, 5%, or 7% of HPMC by weight).
Example 7. A method of making a conductive ink composition, comprising: contacting a copper salt (e.g., copper(II) salt, such as, for example, copper(II) chloride), an aliphatic amine, D-glucose, and water (e.g., deionized water) to form a reaction mixture; and heating the reaction mixture to form the conductive ink composition of any one of claims 1-5.
Example 8. The method of example 7, wherein the aliphatic amine is has from 10 to 20 carbon atoms.
Example 9. The method of example 8, wherein the aliphatic amine is hexadecylamine (HDA).
Example 10. The method of example 9, wherein the molar concentrations of copper(II) chloride, D-glucose, and HDA in the reaction mixture are 19.83 mmol/L, 24.05 mmol/L, and 66.95 mmol/L, respectively.
Example 11. The method of example 9, where the amounts provided are (in the following amounts or amounts based on the ratios of the following amounts): 2.4 g copper(II) chloride; 3.9 g D-glucose; 14.55 g HDA; and 900 mL water.
Example 12. The method of any one of examples 7-9, wherein the reaction mixture further comprises a nickel salt (e.g., nickel chloride), an iron salt, an aluminum salt, or a zinc salt.
Example 13. The method of example 12, wherein the amounts provided are (in the following amounts or amounts based on the ratios of the following amounts): 1.2-2.16 g copper(II) chloride (inclusive and all values in between); 0.182-0.950 g nickel chloride (inclusive and all values in between); 3.9 g D-glucose; 14.55 g HDA; and 900 mL water.
Example 14. The method of any one of claims 7-9, wherein the reaction mixture further comprises nickel chloride, and the molar concentrations of copper(II) chloride, nickel chloride, D-glucose, and HDA in the reaction mixture are 9.92-17.85 mmol/L, 1.56 8.14 mmol/L, 24.05 mmol/L, and 66.95 mmol/L, respectively.
Example 15. The method of any one of examples 7-14, wherein the reaction mixture is heated for a period of time ranging from 5-48 hours (inclusive, and all values in between or higher or lower, for example, 6, 9, 9.5, 10, 11, 12, and 18 hours).
Example 16. The method of any one of examples 7-15, wherein the reaction mixture is heated at a temperature ranging from 15° C. to 100° C. (inclusive, and all values in between or higher or lower, for example, 45° C., 50° C., 55° C., 60° C., 65° C., 70° C., 75° C., 80° C., 85° C., 90° C., or 95° C.).
Example 17. The method of any one of examples 7-16, further comprising stirring the reaction mixture for a period of time ranging from 1-24 hours (inclusive, and all values in between or higher or lower, for example, 6, 9, 9.5, 10, 11, 12, and 18 hours).
Example 18. The method of any one of examples 7-17, further comprising: mixing (hydroxypropyl)methylcellulose (HPMC) with water (e.g., deionized water); and adding the HPMC-water mixture to the conductive ink composition.
Example 19. A method of printing conductive ink, comprising: extruding a conductive ink composition according to example 6 onto a substrate; and washing the extruded ink with an acid (e.g., an organic acid) to remove residual aliphatic amine.
Example 20. An antenna printed using a conductive ink according to example 6.

### FURTHER EXAMPLE

This example provides a description of compositions of the present disclosure and methods of making and using the compositions, and characterization of the compositions.

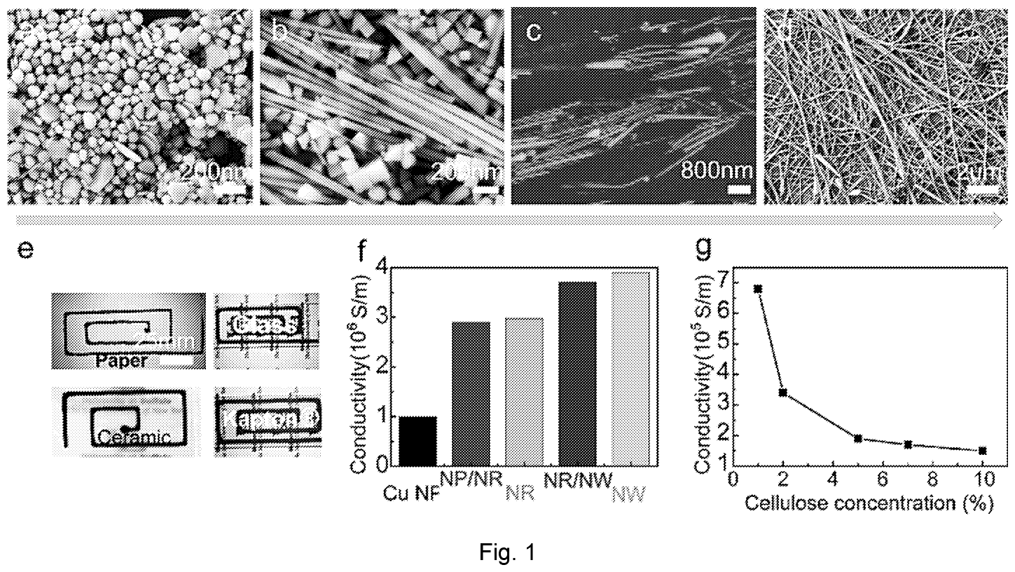

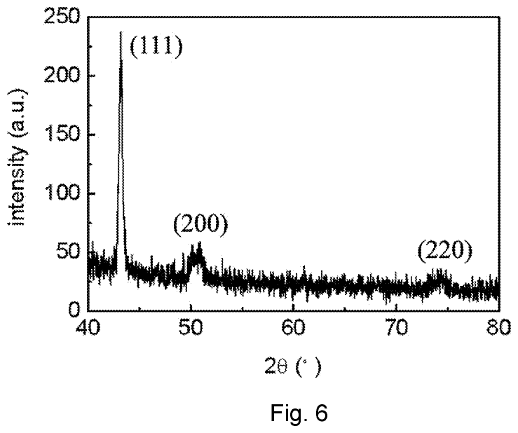

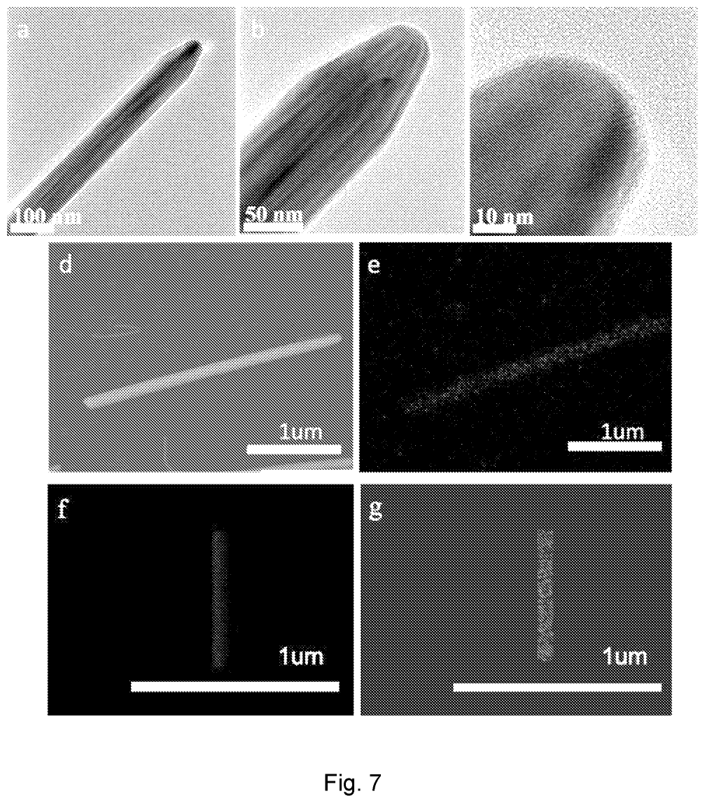

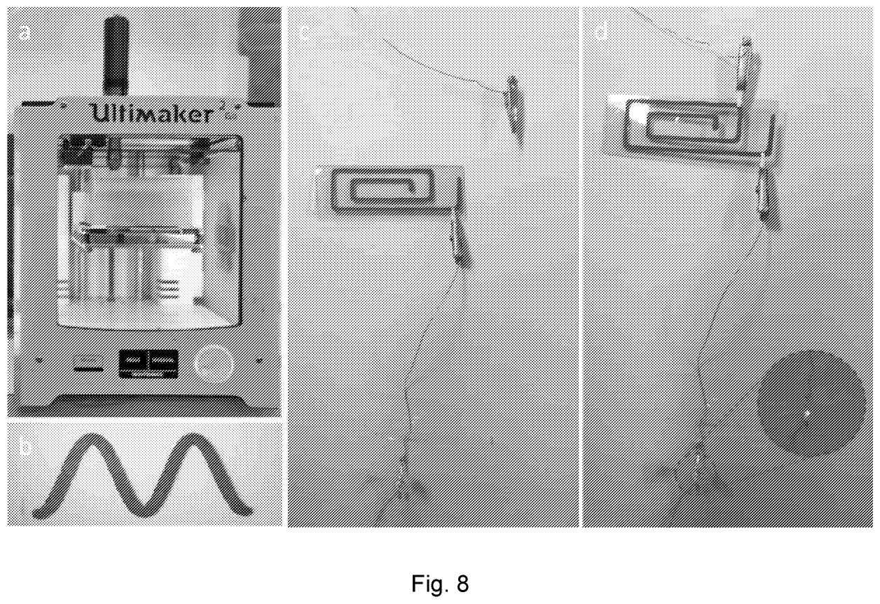

A high throughput and facile approach for the growth of conductive Cu nanostructured materials is attracting a myriad of attention, particularly those highlighting aqueous dispersibility, oxidation resistance, and high quantities for large-scale printable electronics materials. With the aim of obtaining high-yield and uniform Cu nanostructures, we provide an aqueous reduction approach. The morphology and dimension of the as-prepared Cu nanostructures are examined by scanning and transmission electron microscopy (SEM and TEM). Images shown in FIG. 1a-d are taken after solvothermal reaction proceeded for 9, 11, 12, and 18 h (hours), clearly exhibiting the morphological evolution from Cu nanoparticles to nanowires. The initial product after 9 h mainly included Cu nanoparticles with average sizes of 150 nm (FIG. 1a). Beyond 9 h reaction time, the amount of Cu nanoparticles gradually decreased (FIG. 1b,c). As the reaction progresses, Cu nanowires are obtained with an average diameter of 100 nm (FIG. 1d). The Cu nanowire formation has been mainly attributed to the generation of multiply penta-twinned Cu nanoparticles, on which Cu atoms tend to deposit, favoring the isotropic growth from low thermodynamic energy. As the reaction time proceeds, the intrinsic equilibrium drives the Cu atoms favoring the relatively low surface energy of facets, the decahedra structure bounded by the {111} planes. With increasing reaction time, the Cu nanowires of the face-centered cubic (fcc) cubic structure can be formed. The composition of Cu nanowires is confirmed by X-ray diffraction (XRD) and energy-dispersive X-ray spectroscopy (EDS) (FIGS. 6 and 7e). Furthermore, the nanostructured Cu features can be printed onto a variety of dielectric substrates (FIG. 1e) such as glass, paper, PVDF-TIFE, polyimide, flexible YSZ ceramic, etc. Experiments conducted on printed Cu features of different nanostructure geometries (nanoparticles (NP), nanoparticle/nanorod (NR) mixture, and nanowires (NW)) confirm the highest degree of electrical conductivity in Cu nanowires (FIG. 1f). While the samples of Cu nanoparticle and nanorod inks result in electrical conductivities of 1.05×10⁶ and 2.91×10⁶ S/m, Cu nanowire ink was able to achieve a higher value of over 3.85×10⁶ S/m. This can likely be attributed to the formation of a continuous percolation network of Cu nanowires and interfaces, which facilitate the flow of charge carriers throughout the material. Shorter geometries such as nanorods and nanoparticles cannot achieve this same degree of continuity and connectivity. The high aspect ratios of the Cu nanowires may lend themselves to entanglement formation which could impede the printability of the ink solution. To address this, (hydroxypropyl)methylcellulose (HPMC) is added to disperse the Cu nanowires, act as a viscosity modifier, and enhance the interfacial adhesion between the printed features and the dielectric substrates. However, it has proven beneficial to limit the addition of HPMC as there is a negative correlation between HPMC concentration and the conductivity of the printed Cu features. As shown in FIG. 1g, increasing the concentration of HPMC from 1% to 2% decreases the conductivity from 6.82×10⁵ to 3.41×10⁵ S/m and further to under 2×10⁵ S/m when increased to a concentration of 5%. This is due to the insulating nature of cellulose to effect charge transport across the interfaces of the nanowires.

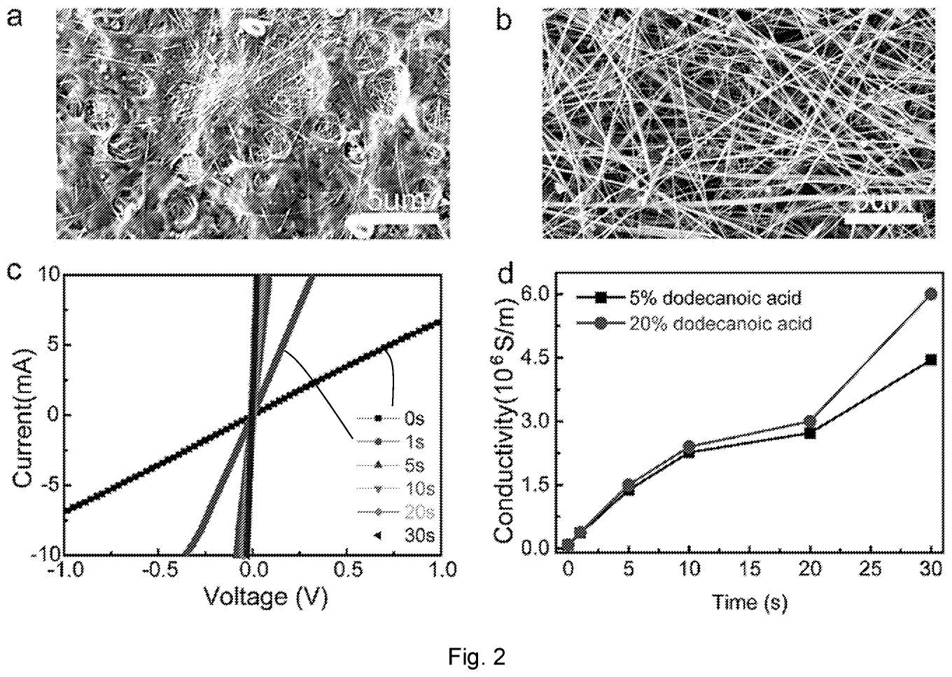

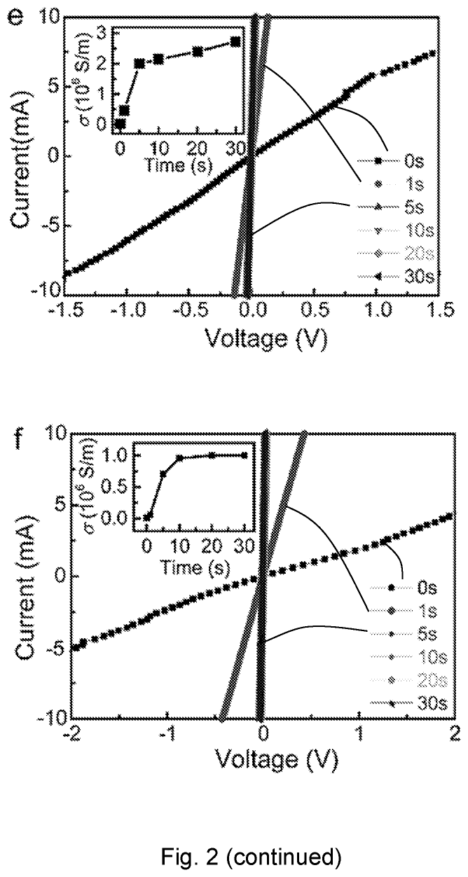

In the Cu ink preparation, the aliphatic amine hexadecylamine (HDA) was used as a capping reagent for Cu nanowire structures, which could not be dissolved in distillation after the hydrothermal reaction. The traditional approach after printing involves high-temperature annealing to remove the polymer additives or capping reagent to enhance the conductivity of printed metallic features. We develop a room temperature in situ solvent exchange approach integrated with a direct printing process, in which the influence of acidic solution on the morphology and conductivity of the Cu conducting features is obtained. This information is acquired from the analysis of electrical conductivity measurements and SEM images (FIG. 2 and FIG. 10). Before the acid treatment, as can be seen by the SEM image in FIG. 2a, the network of Cu nanowires is buried by residual organic HDA ligands adhered to the surface of the Cu nanowires. As stated previously, these ligands can act as a hindrance to the charge transport of Cu nanowire networks and drastically decrease the conductivity of the printed Cu conductors.

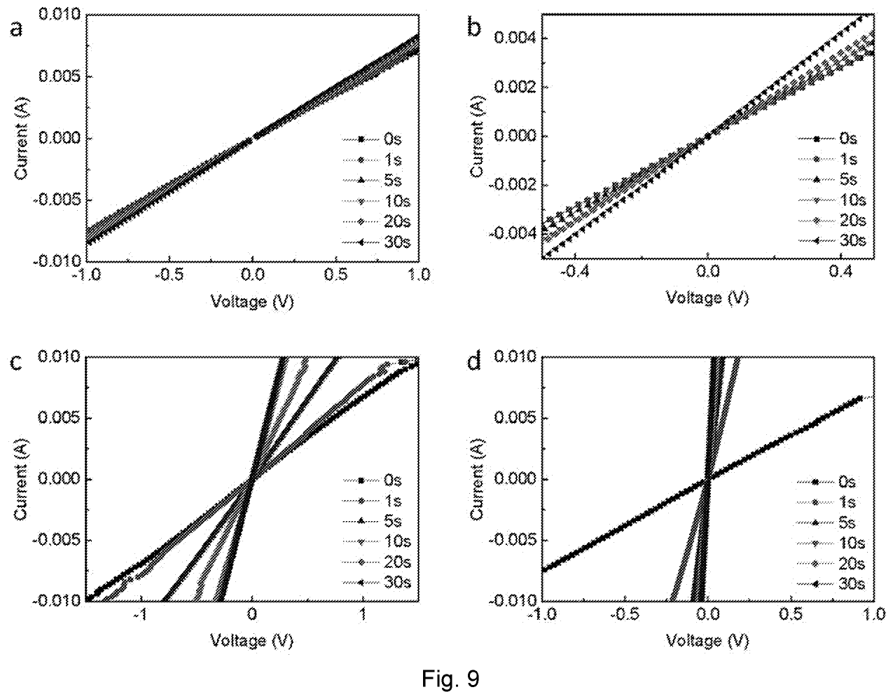

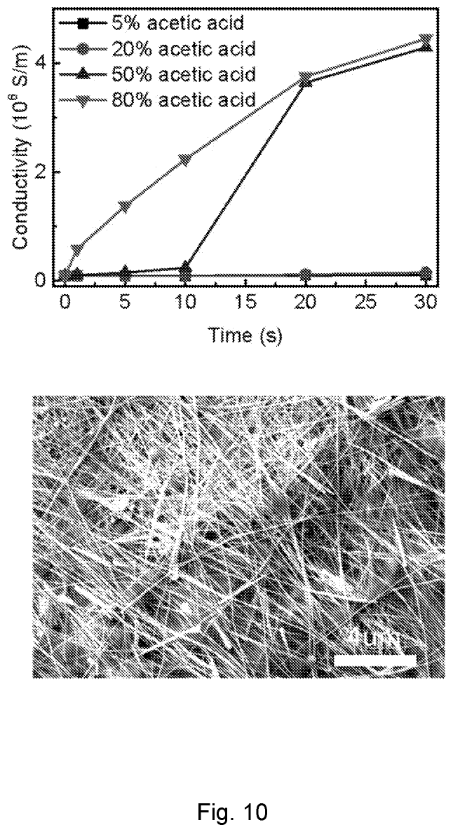

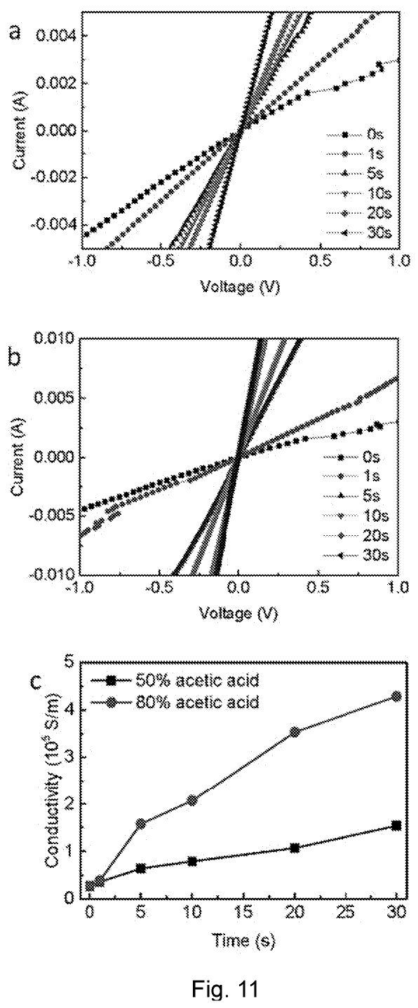

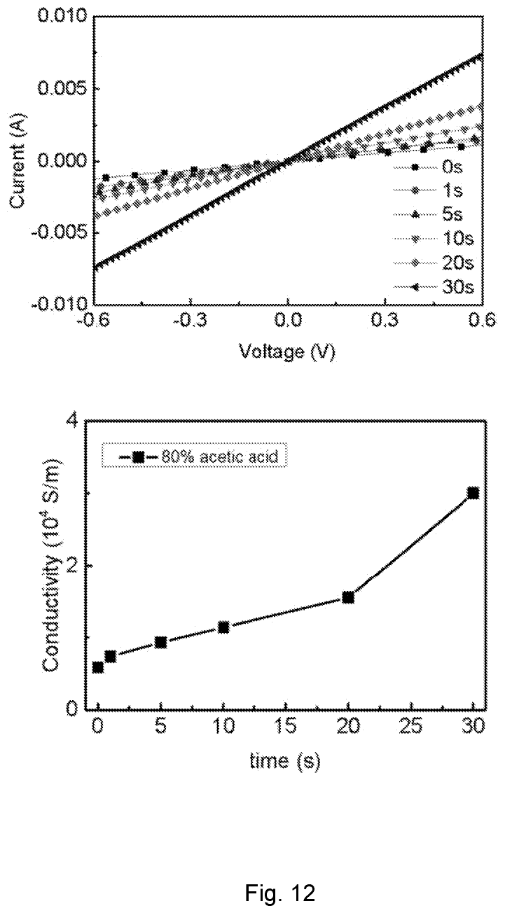

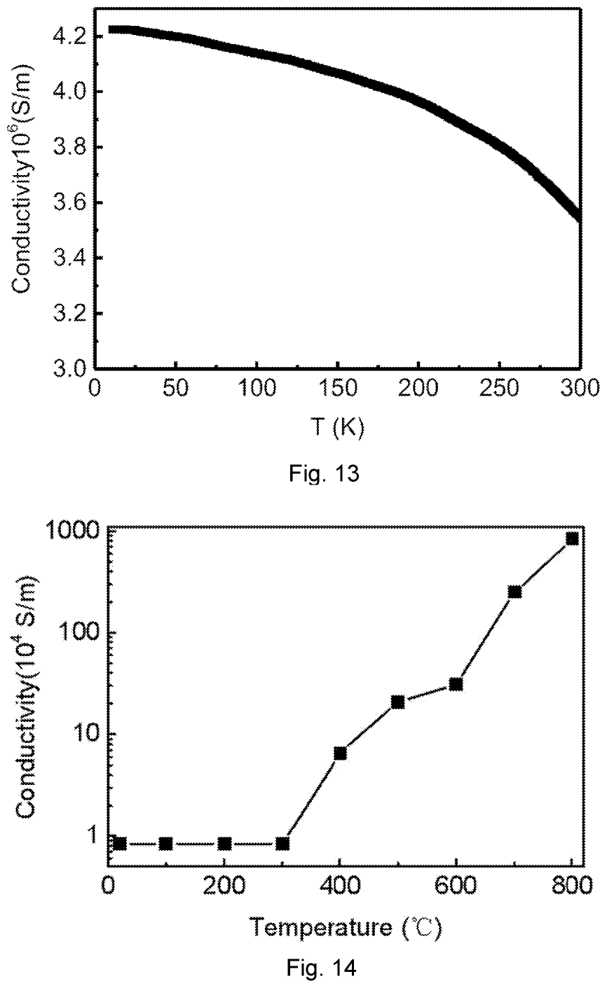

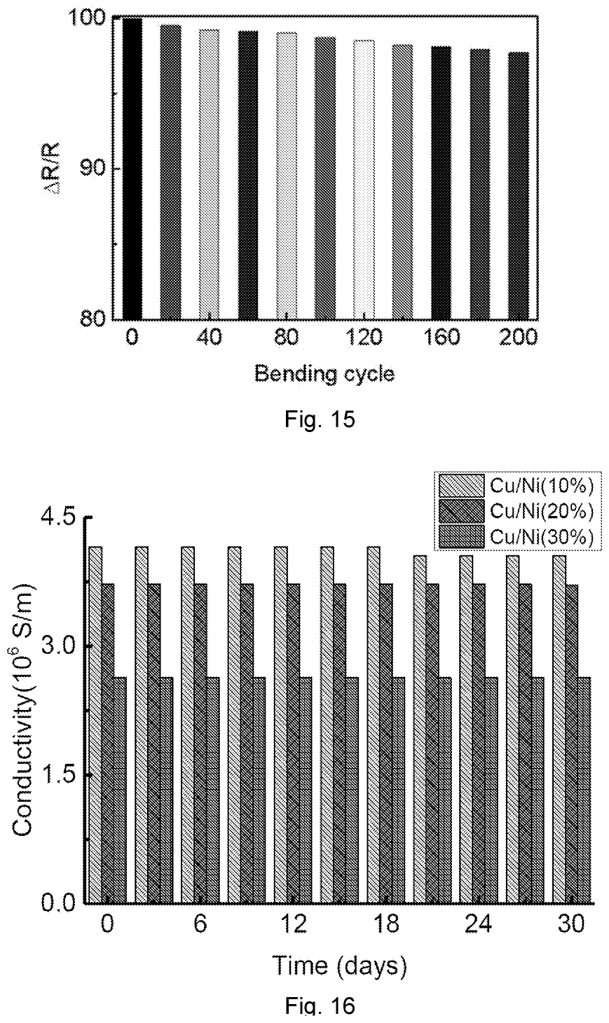

To effectively remove the HDA capping material shown in FIG. 2b and FIGS. 9-12, the printed Cu features are treated with a dodecanoic acid organic solution and acetic acid water-based solution. To understand the effect of the acid treatment on the conductivity, the treatment time is varied from 0 to 30 s. The thickness of the printed Cu is also varied to evaluate the penetrative ability of the solution treatment. We compared two different acid solutions to remove the HDA capping material and achieve the percolation network shown in the FIG. 2 and FIGS. 9-12. FIGS. 9 and 10 indicate the printed Cu has conductivity with 4.21×10⁶ S/m after treated by 80% acetic acid but lower than 20% dodecanoic acid solution. As shown in FIG. 2c,d, the treatment of the 2 μm printed Cu nanowire features with 5% dodecanoic acid increases the conductivity from 9.21×10⁴ to 4.52×10⁶ S/m after 30 s. Increasing this concentration to 20% can bring the conductivity up to 6.09×10⁶ S/m. FIG. 2e,f as well as FIGS. 11 and 12 separately show the effect of respective Cu thicknesses of 4 and 12 μm on the ability of the dodecanoic acid and acetic acid treatment to alter the conductivity of the printed features. As the Cu thickness is increased from 4 to 12 μm, the electrical conductivity after 30 s treatment decreases from 2.75×10⁶ to 1.00×10⁶ S/m with dodecanoic acid and from 4.32×10⁵ to 3.00×10⁴ S/m with acetic acid. This decrease in conductivity can be attributed to the inability of the dodecanoic acid to penetrate deep into the printed conductor trace at greater thicknesses, thus leaving the insulating organic additives to block the charge transport. The result shows the dodecanoic acid organic solution has a better ability to remove the HDA capping than acetic acid, and FIG. 13 indicates temperature-dependent conductivity of the printed Cu conductor.

The conductivity increases from 3.50×10⁶ to 4.22×10⁶ S/m when temperature decreases from 300 to 10 K. It should be noted that HDA is used to illustrate an exemplary embodiment, and that other aliphatic amines (having from 10 to 20 carbon atoms) may be used in making the compositions.

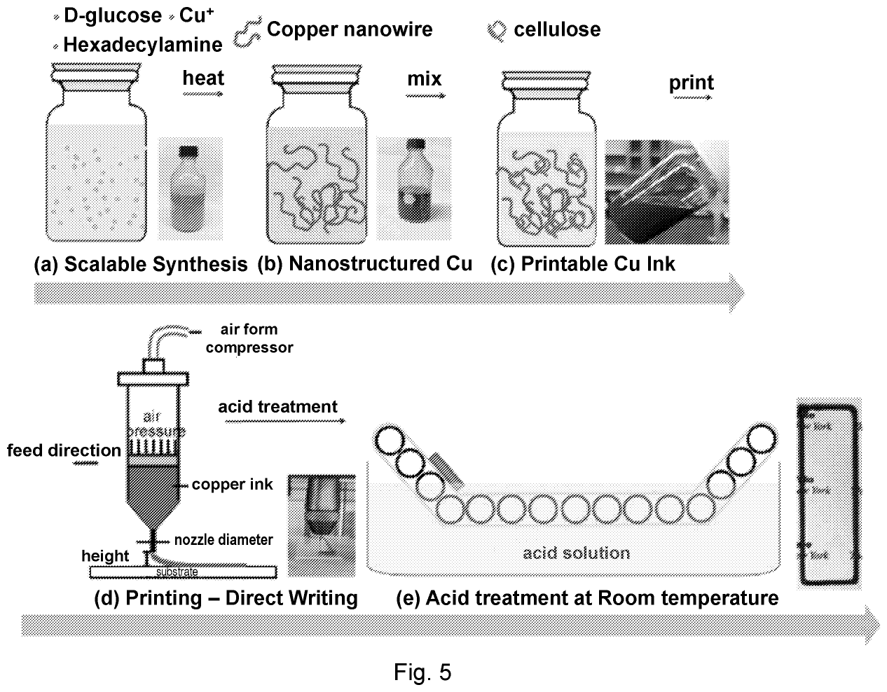

To meet the above criteria, we developed a high-throughput solution growth of earth-abundant Cu nanostructured material ink, which can substantially enhance electrical percolation and flexibility. Through Cu/Ni alloying, the printed metal conductors effectively show oxidation resistance and high-temperature stability. FIG. 5 shows the key manufacturing processes present in the printing of Cu conductive features. The reaction occurs after the combination of copper chloride, hexadecylamine (HDA), and glucose. During the reaction, copper chloride is reduced to Cu nanostructures by glucose and subsequently coated with HDA, which acts as a capping ligand. The Cu slurry is formed by sedimentation, yielding a stable water-soluble Cu feedstock. The viscosity of the retrieved Cu slurry can be controlled by introducing (hydroxypropyl)methyl cellulose (HPMC) into the printable ink preparation. Without high-temperature annealing, we demonstrate that an in situ solvent exchange integrated with a direct writing process can effectively remove additives for highly conductive printed Cu features (>10⁶ S/m) at room temperature. By writing the Cu ink onto an ultrathin, flexible yttria-stabilized zirconia (YSZ) ceramic substrate, we demonstrate conformal high-temperature electronics which integrate radio-frequency antennas with high-temperature sensors for an all-printed conformal electronics platform.

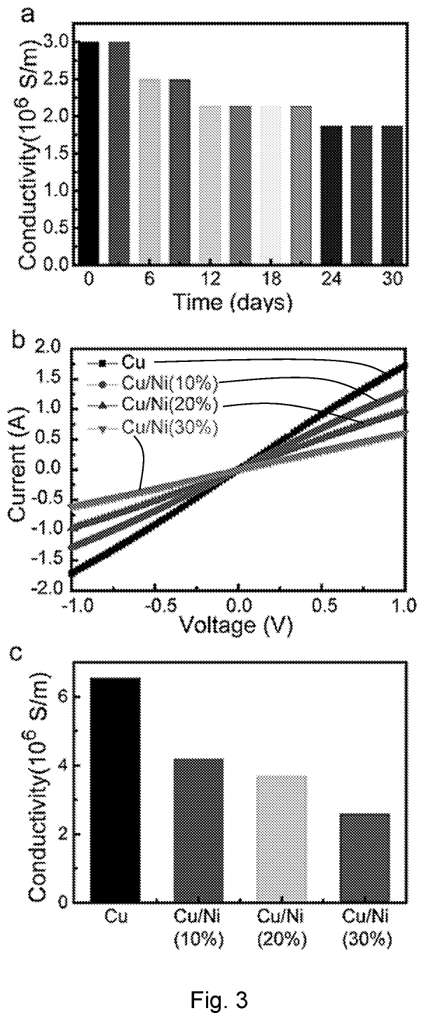

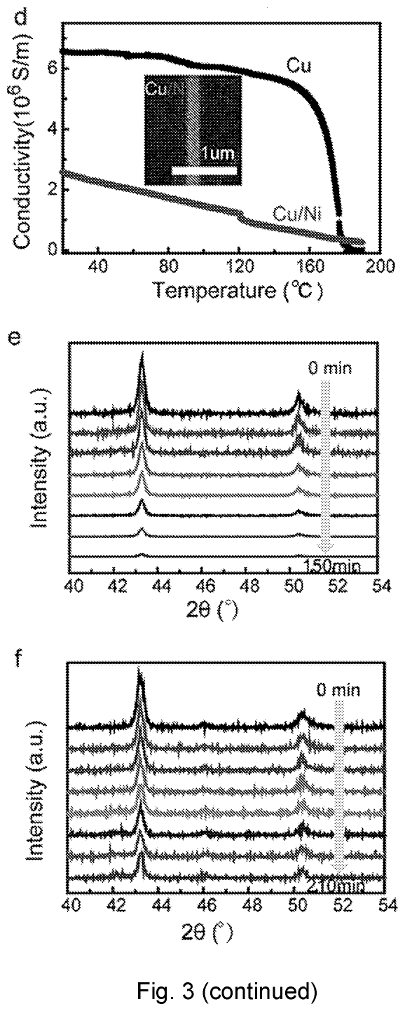

Printed Cu nanowire conductors have shown great promise in terms of conductivity and printability. However, a roadblock against Cu-based printed electronics is the instability of printed Cu conductor in an oxygen-rich environment, especially at elevated temperatures. In some embodiments, to provide the advantageous oxidation resistance, we apply a degree of Cu/Ni alloying to deposit a thin Ni-rich layer on the surface of the Cu/Ni alloying nanowires, creating a core-shell morphology. The Ni-rich shell surface with an average thickness of 10 nm protects the underlying Cu from oxidation without greatly diminishing its conductive capability. Printed pure Cu conductors show instability in air at room temperature, decreasing by nearly 50% from 3.0×10⁶ to 1.7×10⁶ S/m (FIG. 3a) over the course of 30 days. This instability is further shown to result in a steep drop in conductivity as temperatures are increased to over 150° C. (FIG. 3d). The incorporation of Cu/Ni alloying and Ni-rich shell causes a drop in electrical conductivity of Cu conductor (FIG. 3b,c) but increases the stability in the air at elevated temperatures. This Ni-rich shell may have a thickness of 10 nm, as can be seen through EDS mapping shown in the inset of FIG. 3d. Whereas the Cu conductor is shown to decrease in conductivity from 5.41×10⁶ to 0.11×10⁶ S/m from 160 to 190° C., the Cu/Ni conductor only decreases from 0.55×10⁶ to 0.29×10⁶ S/m over the same temperature span. This makes it clear that a Ni shell material may be beneficial to ensure the stability of Cu conductor at elevated temperatures. FIGS. 3e and 3f display the in situ XRD patterns of printed conductors using both Cu and Cu/Ni core-shell nanowire inks under 150° C. Both patterns show initial peaks at 20 values of 43.2° and 50.4°, which correspond to diffraction from the (111) and (200) lattice planes of Cu, respectively. It can be seen that the intensity peaks decrease slightly throughout all in situ readings taken over the course of 210 min in Cu/Ni conductor. Meanwhile, the intensity peaks of the Cu conductor are almost completely gone after 150 min due to the oxidation of the Cu. Other materials may be used in place of nickel. For example, embodiments may use aluminum, zinc, iron, and/or other metals as shells and/or alloyed with copper as a shell. In some embodiments, graphene may be used to encapsulate the copper nanoparticle.

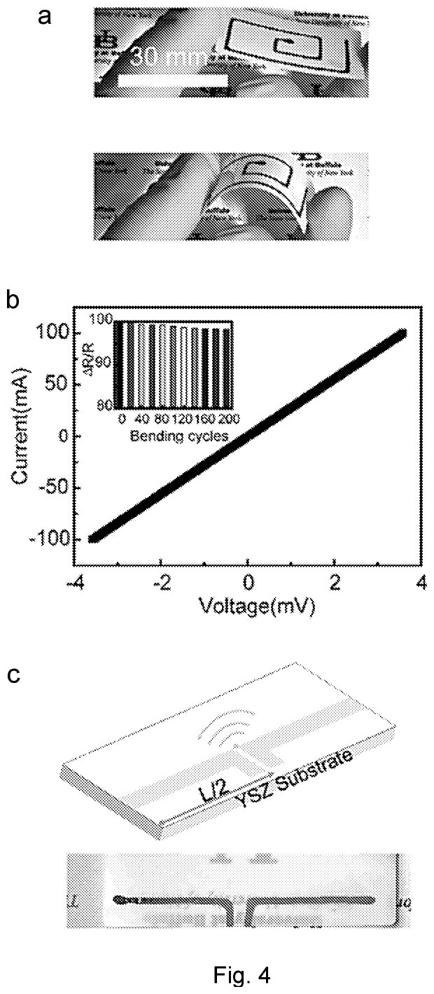

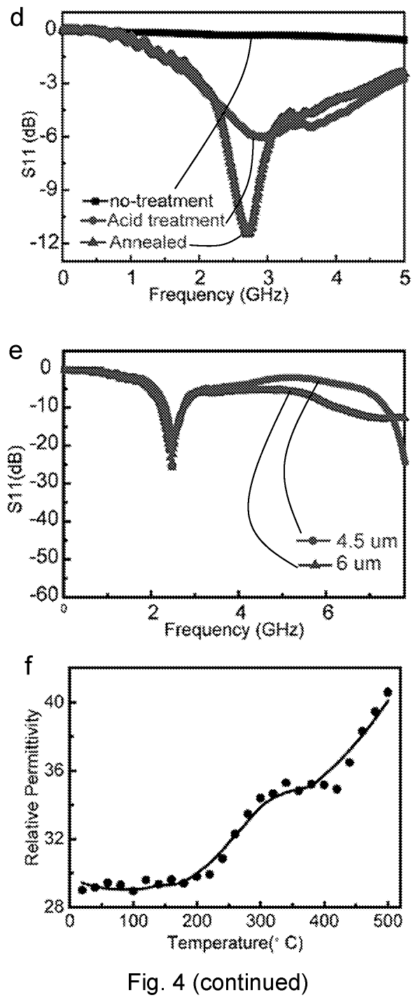

We demonstrate all-printed conformal high-temperature electronics by integrating a radio-frequency antenna with high-temperature sensors through direct writing the Cu ink traces on a printed flexible ceramic YSZ substrate. For the conformal electronics, a series of bending angle tests through an angle of 120° are applied to determine the flexibility and conformal ability of the linear array of Cu traces as shown in FIG. 4a. A dynamic bending cyclic measurement confirms the durability of all-printed devices, in which we measure the resistance changes during 200 bending cycles to evaluate the bending impact on electronic performance (inset of FIG. 4b). The subtle dynamic resistance change of <5% is evidence of the durability of printed devices. Upon annealing of the Cu on flexible ceramic at 800° C. for 10 min, the electrical conductivity of printed Cu features exceeded 1×10⁷ S/m, obtained by using a four-point probe resistance measurement shown in FIG. 4b, which is 3 orders of magnitude higher than that of as-printed Cu conductor and 1 order of magnitude higher than that of solution-treated Cu conductor without annealing. This is also consistent with the results shown in the FIG. 14 which reveals the no-treatment Cu conductor conductivity increases from 6×10³ to 1×10⁷ S/m with the temperature duo to evaporation of HDA. We explore resonant properties of the straight dipole antenna with a total length 47.2 mm, focusing on highly conductive Cu printed features on the flexible dielectric ceramic substrate. We perform one-port scattering parameter measurements of the printed antennas. FIG. 4c show the schematic diagrams and optical photographs of printed Cu-YSZ RF antenna. The scattering parameter S₁₁, usually expressed in decibels, is used to quantify the reflection coefficient, indicating the ratio of reflected power to incident power at the input of the dipole antenna. As shown in FIG. 4d, the reflected power increases with the decrease in conductivity of printed Cu traces. As can be seen in FIG. 4e, resonant frequencies are shown around 2.5 GHz for both Cu thicknesses of 4.5 and 6 μm. The resonance at 2.5 GHz corresponds to the design length of 47.2 mm, suggesting that the conductor thickness is adequate enough for the dipole antenna to operate. The flexible YSZ ceramic substrates provide not only high robustness in manufacturing but also low thermal resistance for high-temperature electronics. More importantly, its temperature dependence of the relative permittivity (FIG. 4f) can serve as a probe for high-temperature sensors. The relative permittivity of all-printed high-temperature sensors are measured as a function of temperature (25-500° C.) with sensitivity (0.05% ° C.⁻¹) and accuracy (15° C.) for real-time high-temperature sensing. The increase of the dielectric constant with temperature can be explained by the conduction contribution from space-charge conductivity. Our observations of all-printed conformal high-temperature electronics and integrating a RF antenna with a high-temperature sensor align with the current interest in dielectric materials at microwave and millimeter wave frequencies.

### Experimental Section

Copper nanowire preparation: 2.4 g of copper chloride, 3.9 g of D-glucose, and 14.55 g of hexadecylamine (HDA) were added into 900 mL of Deionized (DI) water and then stirred for 12 h to obtain a uniform emulsion. 70 mL of the above solution was heated in the hydrothermal reactor for different times (6, 9, 9.5, 10, 11, 12, and 18 h).

Copper-nickel nanowire preparation: Different amounts of copper chloride and nickel chloride (2.16 g of copper chloride, 0.182 g of nickel chloride; 1.92 g of copper chloride, 0.364 g of nickel chloride; 1.68 g of copper chloride, 0.546 g of nickel chloride; 1.2 g of copper chloride, 0.950 g of nickel chloride), 3.9 g of D-glucose, and 14.55 g of hexadecylamine were added into 900 mL of DI water and then stirred for 12 h to obtain a uniform emulsion. 70 mL of the above solution was heated in the reactor for different times (9, 9.5, and 10 h).

Direct writing process, printed Cu conductor fabrication, and testing: For making the ink viable for printing, 2% w/w (hydroxypropyl)methyl cellulose (HPMC) (Sigma-Aldrich, 2% in H2O) was added to DI water and stirred on a magnetic stirring apparatus at 750 rpm and 60° C. for 1 h. For printability, four samples were tested, namely, 12, 13, 14, and 15 h. Five samples were prepared which comprised the HPMC solvent in proportions of 1%, 2%, 5%, 7%, and 10% w/w for each of the four samples of copper ink, equaling to a total of 20 samples. For mixing the copper ink with HPMC to a uniform consistency, a combination of magnetic stirring at 750 rpm and hand mixing was used. In some embodiments, it was found that a viscosity of 100 centipoise or lower (for example, up to 2 orders of magnitude lower) may be advantageous for printing using the disclosed processes.

The direct writing apparatus was of an Ultimaker 2 Go air compressor along with a pressure multiplier (Nordson EFD). A syringe of volume 3 mL with a nozzle size of 250 μm was utilized for printing the synthesized solution. The pressure for material deposition varied between 15.4 and 18.9 psi. Substrates acting as a base for the print deposition included glass (Micro Slides, Plain manufactured by Corning Inc., NY), ceramic (Tapecon), paper, Kapton tape (a polyimide film) on a glass slide, Teflon tape on a glass slide, and flexible ceramics. The print quality can be dependent on air pressure, height between the substrate and the nozzle, feed speed of the nozzle movement, and ink viscosity. The print speed varied from 450 to 850 mm/min. In addition, three different thicknesses for each type of ink were printed using this process, which involved depositing ink in a single pass for a single layer, a double pass for two layers, and a triple pass for three layers. The printed samples were post-treated with organic acid for 30 s to wash off excess additives. The electrical conductivity measurements were performed using a four-probe conductivity meter (Keithley 2450). We perform one-port scattering parameter measurements of the printed antennas with attached SMA connectors using a Keysight N5242A PNA-X network analyzer.

Although the present disclosure has been described with respect to one or more particular embodiments, it will be understood that other embodiments of the present disclosure may be made without departing from the spirit and scope of the present disclosure.

1. A conductive ink composition, comprising a slurry of copper nanoparticles in water.

2. The conductive ink composition of claim 1, wherein the copper nanoparticles are nanowires.

3. The conductive ink of claim 2, wherein the nanowires have an average diameter ranging from 20-150 nm, inclusive, and all values in between.

4. The conductive ink composition of claim 1, wherein each of the copper nanoparticles comprises copper or a copper alloy.

5. The conductive ink composition of claim 4, wherein each of the copper nanoparticles is encapsulated by nickel, a nickel-rich material, zinc, aluminum, iron, or other metals or metal alloys, or graphene.

6. The conductive ink composition of claim 5, wherein the nickel encapsulation has an average thickness ranging from 10-30 nm, inclusive, and all values in between.

7. The conductive ink composition of claim 1, further comprising (hydroxypropyl)methyl cellulose (HPMC).

8. A method of making a conductive ink composition, comprising:
contacting a copper salt, an aliphatic amine, D-glucose, and water to form a reaction mixture; and
heating the reaction mixture to form the conductive ink composition of claim 1.

9. The method of claim 8, wherein the aliphatic amine has from 10 to 20 carbon atoms, inclusive.

10. The method of claim 9, wherein the aliphatic amine is hexadecylamine (HDA).

11. The method of claim 10, wherein the molar concentrations of copper(II) chloride, D-glucose, and HDA in the reaction mixture are 19.83 mmol/L, 24.05 mmol/L, and 66.95 mmol/L, respectively.

12. The method of claim 8, wherein the reaction mixture further comprises a nickel salt, an iron salt, an aluminum salt, or a zinc salt.

13. The method of claim 8, wherein the reaction mixture further comprises nickel chloride, and the molar concentrations of copper(II) chloride, nickel chloride, D-glucose, and HDA in the reaction mixture are 9.92-17.85 mmol/L, 1.56-8.14 mmol/L, 24.05 mmol/L, and 66.95 mmol/L, respectively.

14. The method of claim 8, wherein the reaction mixture is heated for a period of time ranging from 5-48 hours (inclusive, and all values in between or higher or lower, for example, 6, 9, 9.5, 10, 11, 12, and 18 hours).

15. The method of claim 8, wherein the reaction mixture is heated at a temperature ranging from 15° C. to 100° C. inclusive, and all values in between.

16. The method of claim 8, further comprising stirring the reaction mixture for a period of time ranging from 1-24 hours inclusive, and all values in between.

17. The method of claim 8, further comprising:
mixing (hydroxypropyl)methylcellulose (HPMC) with water (e.g., deionized water); and
adding the HPMC-water mixture to the conductive ink composition.

18. A method of printing conductive ink, comprising:
extruding a conductive ink composition according to claim 7 onto a substrate; and
washing the extruded ink with an acid to remove residual aliphatic amine.

19. An antenna printed using a conductive ink according to claim 7.
